(19) United States
(12) Patent Application Publication
(10) Pub. No.: US 2024/0113174 A1
(43) Pub. Date: Apr. 4, 2024

(54) LAMINATE AND METHOD OF MANUFACTURING LAMINATE

(71) Applicants: Japan Display Inc., Tokyo (JP); MEIJO UNIVERSITY, Nagoya-shi (JP)

(72) Inventors: Masanobu IKEDA, Tokyo (JP); Arichika ISHIDA, Tokyo (JP); Satoshi KAMIYAMA, Nagoya-shi (JP); Motoaki IWAYA, Nagoya-shi (JP); Tetsuya TAKEUCHI, Nagoya-shi (JP)

(73) Assignees: Japan Display Inc., Tokyo (JP); MEIJO UNIVERSITY, Nagoya-shi (JP)

(21) Appl. No.: 18/532,505

(22) Filed: Dec. 7, 2023

Related U.S. Application Data
(63) Continuation of application No. PCT/JP2022/022163, filed on May 31, 2022.

(30) Foreign Application Priority Data
Jun. 11, 2021 (JP) 2021-098291

(51) Int. Cl. H01L 29/20; H01L 21/02

(52) U.S. Cl. CPC H01L 29/2003; H01L 21/02422; H01L 21/0254; H01L 21/02631; H01L 33/32

(57) ABSTRACT

A laminate includes an amorphous glass substrate, and an AlN layer formed on the amorphous glass substrate. The AlN layer is c-axis oriented on the amorphous glass substrate, a glass transition temperature (Tg) of the amorphous glass substrate is 720° C. to 810° C., a coefficient of thermal expansion (CTE) of the amorphous glass substrate is 3.5×10⁻⁶ [1/K] to 4.0×10⁻⁶ [1/K], and a softening point of the amorphous glass substrate is 950° C. to 1050° C.

### CROSS-REFERENCE TO RELATED APPLICATION

This application is a continuation of PCT international application Ser. No. PCT/JP2022/022163 filed on May 31, 2022, which designates the United States, incorporated herein by reference, and which claims the benefit of priority from Japanese Patent Application No. 2021-098291 filed on Jun. 11, 2021, incorporated herein by reference.

### BACKGROUND

### 1. Technical Field

The present disclosure relates to a laminate and a method of manufacturing the laminate.

### 2. Description of the Related Art

It has been known that when GaN is grown on a sapphire substrate, an AlN buffer layer is interposed between the sapphire substrate and GaN (see, for example, H. Amano, N. Sawaki, I. Akasaki and Y. Toyoda: Appl. Phys. Lett. 48 363, (1986)). This technology has the problem of high deposition temperature and high substrate price.

Therefore, attempts have been made to grow GaN by using glass as a substrate (see, for example, Japanese Patent Application Laid-open Publication No. H11-243229, Japanese Patent Application Laid-open Publication No. 2000-124140, and WO 2020/188851).

However, for GaN to be deposited and formed on a glass substrate, crystallinity needs to be improved to the point where GaN has c-axis orientation. To improve the crystallinity of GaN, AlN that serves as a base layer needs to have c-axis orientation.

It is an object of the present disclosure to provide a laminate that promotes high-quality crystal growth of a GaN layer and a method of manufacturing the laminate.

### SUMMARY

A laminate according to an embodiment of the present disclosure includes an amorphous glass substrate, and an AlN layer formed on the amorphous glass substrate. The AlN layer is c-axis oriented on the amorphous glass substrate, a glass transition temperature (Tg) of the amorphous glass substrate is 720° C. to 810° C., a coefficient of thermal expansion (CTE) of the amorphous glass substrate is 3.5×10⁻⁶ [1/K] to 4.0×10⁻⁶ [1/K], and a softening point of the amorphous glass substrate is 950° C. to 1050° C.

A method of manufacturing a laminate according to an embodiment is disclosed. The method includes preparing an amorphous glass substrate having a glass transition temperature (Tg) of 720° C. to 810° C., a coefficient of thermal expansion (CTE) of 3.5×10⁻⁶ [1/K] to 4.0×10⁻⁶ [1/K], and a softening point of 950° C. to 1050° C., and forming an AlN layer on the amorphous glass substrate at a deposition temperature of 400° C. to 600° C.

### BRIEF DESCRIPTION OF THE DRAWINGS

FIG. 1 is an explanatory diagram illustrating a method of manufacturing a laminate according to a first embodiment;

FIG. 2 is a sectional view of the laminate according to the first embodiment;

FIG. 3 is a schematic diagram illustrating a first deposition step of the first embodiment;

FIG. 4 is a table illustrating evaluation results of an evaluation example of the first embodiment;

FIG. 5 is a diagram illustrating an XRD spectrum of a first example;

FIG. 6 is a diagram illustrating the XRD spectrum of the first example;

FIG. 7 is a diagram illustrating an XRD spectrum of a first comparative example;

FIG. 8 is a diagram illustrating an XRD spectrum of a second comparative example;

FIG. 9 is a sectional view of a semiconductor device including the laminate according to a second embodiment;

FIG. 10 is an explanatory diagram illustrating a method of manufacturing the semiconductor device including the laminate according to the second embodiment;

FIG. 11 is a sectional view of a semiconductor device including the laminate according to a third embodiment; and

FIG. 12 is an explanatory diagram illustrating a method of manufacturing the semiconductor device including the laminate according to the third embodiment.

### DETAILED DESCRIPTION

Embodiments of the present disclosure will be described in detail with reference to the drawings. The present disclosure is not limited by what is described in the following embodiments. Components described below include those that could be easily assumed by a person skilled in the art and those that are substantially the same. Furthermore, the components described below can be combined as appropriate. What is disclosed herein is merely an example, and any appropriate modification that could be easily conceived of by a person skilled in the art, while maintaining the spirit of the invention, is naturally included in the scope of the present disclosure. The drawings may schematically illustrate the width, thickness, shape, and the like of parts compared to the actual mode for the sake of clarity of explanation, but this is merely an example and does not limit the interpretation of the present disclosure. In the present specification and figures, elements similar to those described earlier with respect to figures already mentioned are given the same reference signs and detailed description thereof may be omitted as appropriate.

### First Embodiment

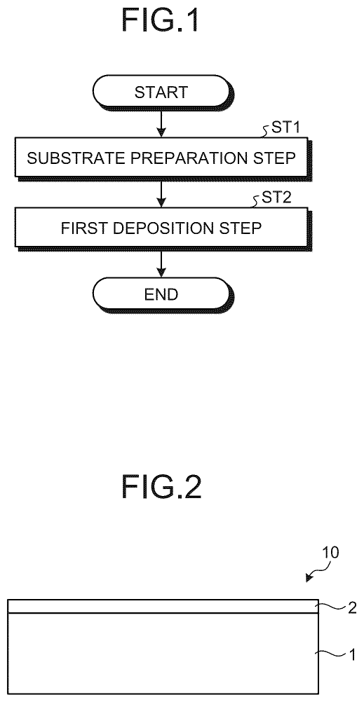

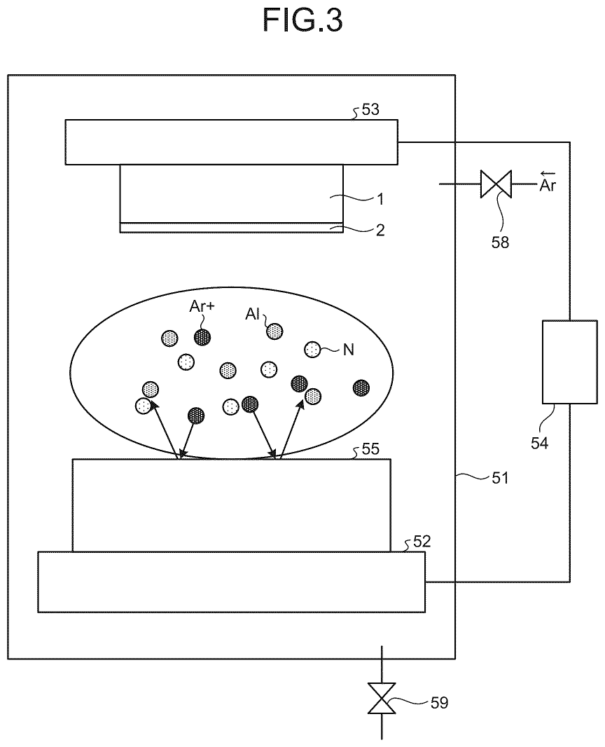

FIG. 1 is an explanatory diagram illustrating a method of manufacturing a laminate according to a first embodiment. FIG. 2 is a sectional view of the laminate according to the first embodiment. FIG. 3 is a schematic diagram illustrating a first deposition step of the first embodiment.

As illustrated in FIG. 1, at a substrate preparation step, an amorphous glass substrate 1 is prepared as a substrate for a laminate 10 illustrated in FIG. 2 (step ST1). In the present disclosure, the substrate preparation step is the first step. The glass transition temperature (Tg) of the amorphous glass substrate 1 is 720° C. to 810° C. The coefficient of thermal expansion (CTE) of the amorphous glass substrate 1 is 3.5×10⁻⁶ [1/K] to 4.0×10⁻⁶ [1/K]. The softening point of the amorphous glass substrate 1 is 950° C. to 1050° C.

At a first deposition step (step ST2), an AlN layer 2 is deposited in direct contact with the amorphous glass substrate 1, as illustrated in FIG. 2. In the present disclosure, the first deposition step is the second step. At the first deposition step (step ST2), the AlN layer 2 is deposited as a thin film not by metal organic chemical vapor deposition (MOCVD) but by a sputtering apparatus 51 illustrated in FIG. 3. Thus, the deposition rate of the AlN layer is increased and the manufacturing cost of the laminate 10 is reduced.

As illustrated in FIG. 3, the amorphous glass substrate 1 is attached to an anode 53 of the sputtering apparatus 51, and an Al target 55 is attached to a cathode 52 of the sputtering apparatus. The anode 53 and the cathode 52 are each coupled to a power supply 54. The sputtering apparatus 51 closes an exhaust valve 59 and fills the sputtering apparatus 51 with argon gas and nitrogen gas through an argon inlet valve and a nitrogen inlet valve.

At the first deposition step (step ST2), the AlN layer 2 is deposited directly on the amorphous glass substrate 1 by magnetron sputtering at a deposition temperature of 400° C. to 600° C. If the deposition temperature is lower than 400° C., the AlN layer 2 is difficult to be c-axis oriented, and if the deposition temperature exceeds 600° C., the AlN layer 2 is difficult to be c-axis oriented due to degassing from a deposition chamber. Because the AlN layer 2 is deposited at a temperature of 400° C. to 600° C., the AlN layer 2 can be deposited on amorphous glass with c-axis orientation. The CTE of the AlN layer 2 to be deposited is 4.2×10⁻⁶ [1/K] to 5.3×10⁻⁶ [1/K]. Even if the deposition temperature increases and the amorphous glass substrate 1 thermally expands, the CTE of the amorphous glass substrate 1 is close to the CTE of the AlN layer 2, making it difficult for thermal expansion deviations to occur and facilitating c-axis orientation of the AlN layer 2.

The Tg of the amorphous glass substrate 1 is 720° C. to 810° C., and the softening point of the amorphous glass substrate 1 is 950° C. to 1050° C. The low deposition temperature allows the amorphous glass substrate 1 to maintain high stability during deposition. If the Tg of the amorphous glass substrate 1 is lower than 720° C. and the softening point is lower than 950° C., the deposited AlN layer 2 is difficult to be c-axis oriented. If the Tg of the amorphous glass substrate 1 exceeds 810° C. and the softening point exceeds 1050° C., the deposition temperature can be set higher, but the deposited AlN is difficult to be c-axis oriented.

The thickness of the amorphous glass substrate 1 is 0.4 mm to 1.0 mm. If the thickness of the amorphous glass substrate 1 is smaller than 0.4 mm, the amorphous glass substrate 1 tends to warp due to film stress of the AlN layer 2 caused by the deposition temperature. If the thickness of the amorphous glass substrate 1 exceeds 1.0 mm, the substrate tends to be difficult to be transported at steps after the deposition process of the AlN layer 2 when a semiconductor device is formed, which is not preferable for reducing product and manufacturing costs. The film thickness of the AlN layer 2 is 20 nm to 400 nm. If the film thickness of the AlN layer 2 is smaller than 20 nm, the AlN layer 2 tends to be difficult to be c-axis oriented. If the film thickness of the AlN layer exceeds 400 nm, the substrate tends to warp due to the film stress of the AlN layer 2.

### Evaluation Example

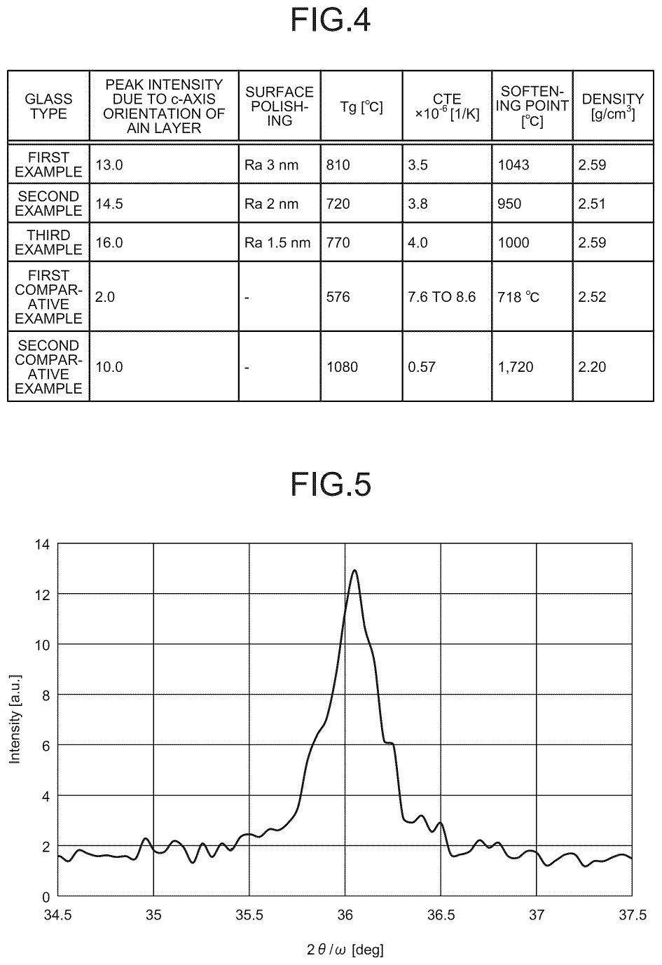

FIG. 4 is a table illustrating evaluation results of an evaluation example of the first embodiment. Respective substrates were prepared for a first example, a second example, a third example, a first comparative example, and a second comparative example.

The composition of the substrate in the first example is an alkaline-earth aluminoborosilicate glass.

The composition of the substrate in the second example is an alkali-free aluminosilicate glass.

The composition of the substrate in the third example is an alkali-free aluminosilicate glass, which is different from that in the second example.

The first comparative example is a high-heat-resistant borosilicate crown glass called BK7.

The second comparative example is quartz.

The thickness of the substrate for each of the first example, the second example, the third example, the first comparative example, and the second comparative example is 0.50 mm. The Tg, CTE, softening point, and density for each of the first example, the second example, the third example, the first comparative example, and the second comparative example are illustrated in FIG. 4.

The arithmetic mean roughness (Ra) of the substrate surfaces of the first example, the second example, and the third example were measured, and are illustrated in FIG. 4. The Ra was measured by an atomic force microscope (AFM).

As illustrated in the first to third examples, the Ra on the surface of the amorphous glass substrate 1 is equal to or less than 3 nm. If the Ra on the surface of the amorphous glass substrate 1 exceeds 3 nm, the surface is desirably polished.

A 200 nm AlN layer was deposited on the respective substrate surfaces of the first example, the second example, the third example, the first comparative example, and the second comparative example by magnetron sputtering at a deposition temperature of 500° C.

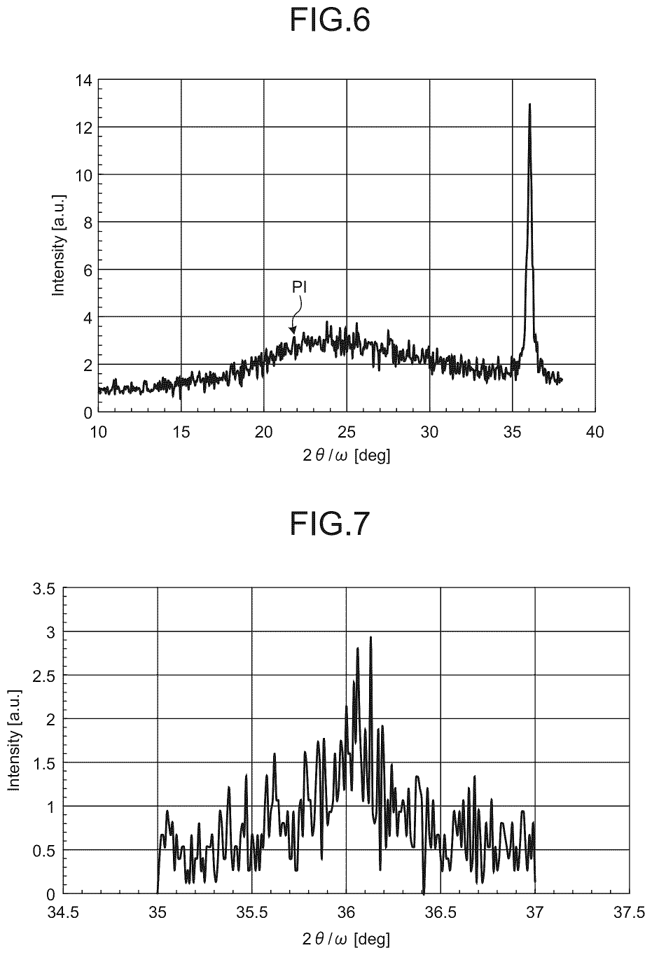

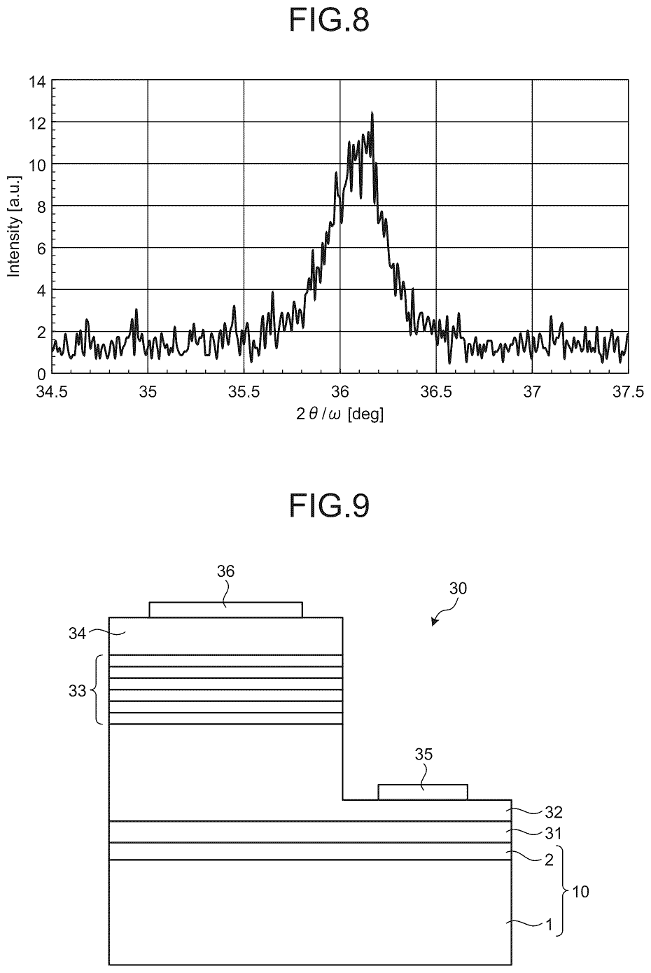

X-ray diffraction (XRD) measurements of the laminate 10 were performed on the laminate in which the AlN layer was deposited for each of the first example, the second example, the third example, the first comparative example, and the second comparative example. FIG. 5 is a diagram illustrating an XRD spectrum of the first example. FIG. 6 is a diagram illustrating the XRD spectrum of the first example. FIG. 5 is an enlarged view of the rotational angle of 2θ/ω 36 [deg] in FIG. 6. FIG. 7 is a diagram illustrating an XRD spectrum of the first comparative example. FIG. 8 is a diagram illustrating an XRD spectrum of the second comparative example. In the XRD spectra illustrated in FIGS. 5 to 8, the vertical axis is the X-ray diffraction intensity (arbitrary units) and the horizontal axis is the rotation angle 2θ [deg]. The XRD spectra were measured using an X-ray diffractometer manufactured by Rigaku Corporation. A characteristic X-ray of CuKα (wavelength: 1.5418 Å) was used as the X-ray source, and the XRD spectrum was measured by X-ray diffraction measurement in 2θ-ω mode (or co mode). As a result, the peak intensity around 36 [deg] of the rotation angle 2θ/ω [deg] was estimated to be due to the c-axis orientation of the AlN layer and is listed in Table 1.

In the XRD spectra illustrated in FIGS. 5 to 8, the vertical axis is the X-ray diffraction intensity (arbitrary units) and the horizontal axis is the rotation angle 20 [deg]. The XRD spectra were measured using an X-ray diffractometer manufactured by Rigaku Corporation.

The peak intensity around 36 [deg] illustrated in FIG. 5 is clearly larger than the peak intensity around 36 [deg] illustrated in FIGS. 7 and 8.

As illustrated in FIG. 6, the substrate in the first example exhibits a broad XRD spectrum, indicating that it is an amorphous glass substrate. Although not illustrated in the figures, the substrates in the second example and the third example are also amorphous glass substrates because they exhibit broad XRD spectra.

The peak intensity PI around 22 [deg] in the XRD spectrum illustrated in FIG. 6 indicates the presence of a local Si—O crystal structure. It was confirmed that the presence of this Si—O crystal structure facilitates c-axis orientation of the AlN layer 2. The regular Si—O crystal structure present on the surface of the amorphous glass substrate 1 facilitates the c-axis orientation of the AlN layer 2.

### Second Embodiment

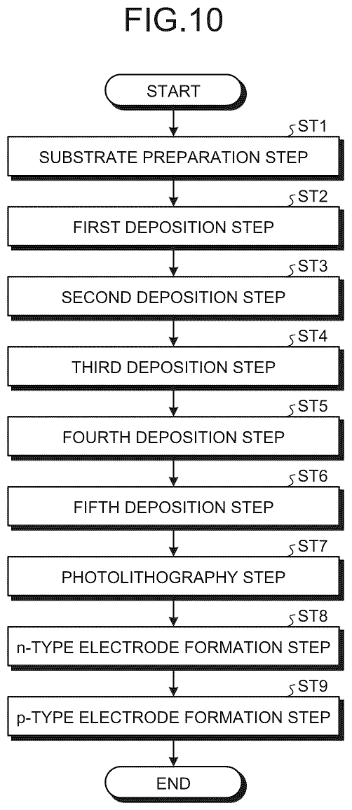

FIG. 9 is a sectional view of a semiconductor device including the laminate according to a second embodiment. FIG. 10 is an explanatory diagram illustrating a method of manufacturing the semiconductor device including the laminate according to the second embodiment. In the second embodiment, the same configuration and steps as those in the first embodiment are given the same reference signs and detailed description thereof is omitted. A semiconductor device 30 illustrated in FIG. 9 is a light emitting diode (LED).

As illustrated in FIG. 9, the semiconductor device 30 has an electrode 35 electrically coupled to the cathode and an electrode 36 electrically coupled to the anode. The semiconductor device 30 is formed on the laminate 10 of the first embodiment. The semiconductor device 30 has a bonding layer 31, an n-type cladding layer 32, a light emitting layer 33, a p-type cladding layer 34. The light emitting layer 33 has a multiple quantum well structure (MQW structure) in which a well layer and a barrier layer made up of several atomic layers are periodically stacked for high efficiency.

As illustrated in FIG. 10, after the aforementioned first deposition step (step ST2), a second deposition step is performed. At the second deposition step, the bonding layer 31 is deposited on the AlN layer 2 (step ST3). The bonding layer 31 is an undoped GaN layer.

After the second deposition step (step ST3), a third deposition step is performed. At the third deposition step, the n-type cladding layer 32 of gallium nitride (GaN) doped with silicon (Si) is deposited on the bonding layer 31 (step ST4).

After the third deposition step (step ST4), a fourth deposition step is performed. At the fourth deposition step, the light emitting layer 33 in which a plurality of layers of indium gallium nitride (InxGa(1-x)N) and GaN are repeatedly stacked on the n-type cladding layer 32 (step ST5).

After the fourth deposition step (step ST5), a fifth deposition step is performed. At the fifth deposition step, the p-type cladding layer 34 of GaN doped with magnesium (Mg) is deposited on the n-type cladding layer 32 (step ST6).

After the fifth deposition step (step ST6), patterning is performed by plasma etching, for example, at a photolithography step (step ST7).

After the photolithography step (step ST7), a n-type electrode formation step is performed. At the n-type electrode formation step, the electrode 35 is deposited by indium (In) (step ST8).

After the n-type electrode formation step (step ST8), a p-type electrode formation step is performed. At the p-type electrode formation step, the electrode 36 of palladium-gold alloy (PdAu) is deposited (step ST9).

### Third Embodiment

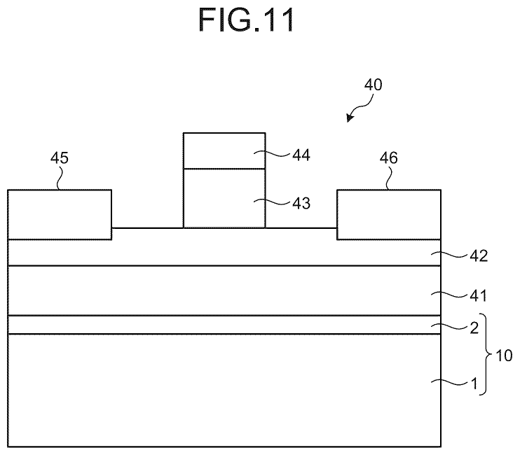

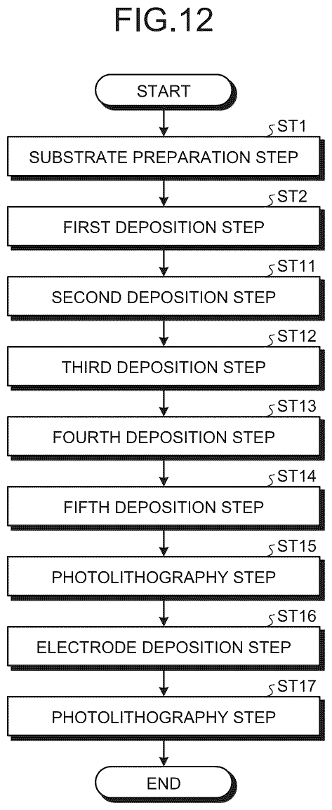

FIG. 11 is a sectional view of a semiconductor device including the laminate according to a third embodiment. FIG. 12 is an explanatory diagram illustrating a method of manufacturing the semiconductor device including the laminate according to the third embodiment. In the third embodiment, the same configuration and steps as those in the first embodiment are given the same reference signs and detailed description thereof is omitted. A semiconductor device 40 illustrated in FIG. 11 is a high electron mobility transistor (HEMT) device.

As illustrated in FIG. 11, the semiconductor device 40 has an electron travel layer 41, an electron supply layer 42, a barrier layer 43, a gate electrode 44, a source electrode 45, and a drain electrode 46. The gate electrode 44 sandwiched between the source electrode 45 and the drain electrode 46 forms a Schottky contact with the barrier layer 43.

As illustrated in FIG. 12, after the aforementioned first deposition step (step ST2), a second deposition step is performed. At the second deposition step, the electron travel layer 41 is deposited on the AlN layer 2 (step ST11). The electron travel layer 41 is an undoped GaN layer.

After the second deposition step (step ST11), a third deposition step is performed. At the third deposition step, the electron supply layer 42 is deposited on the electron travel layer 41 (step ST12). The electron supply layer 42 is undoped InxGa(1-x)N.

After the third deposition step (step ST12), a fourth deposition step is performed. At the fourth deposition step, the barrier layer 43 is deposited on the electron supply layer 42 (step ST13). The barrier layer 43 is GaN doped with Mg.

After the fourth deposition step (step ST13), a fifth deposition step is performed. At the fifth deposition step, the gate electrode 44 is deposited on the barrier layer 43 (step ST14).

After the fifth deposition step (step ST14), the barrier layer 43 and the gate electrode 44 are patterned in shape by plasma etching, for example, at a photolithography step (step ST15).

After the photolithography step (step ST15), an electrode deposition step is performed. At the electrode deposition step, metal layers that will become the source electrode 45 and the drain electrode 46 are formed (step ST16).

After the electrode deposition step (step ST16), at a photolithography step (step ST17), the metal layers formed at the electrode deposition step (step ST16) are patterned in shape by plasma etching, for example, to form the source electrode 45 and the drain electrode 46.

Although preferred embodiments of the present disclosure have been described above, the present disclosure is not limited to such embodiments. What is disclosed in the embodiments is merely an example, and various modifications can be made without departing from the spirit of the present disclosure. Any modification made to the extent not departing from the spirit of the present disclosure naturally belongs to the technical scope of the present disclosure. At least one of various omissions, substitutions, and modifications of the components can be made to the extent not departing from the gist of the aforementioned embodiments and modifications.

What is claimed is:

1. A laminate comprising:
an amorphous glass substrate; and
an AlN layer formed on the amorphous glass substrate, wherein
the AlN layer is c-axis oriented on the amorphous glass substrate,
a glass transition temperature (Tg) of the amorphous glass substrate is 720° C. to 810° C.,
a coefficient of thermal expansion (CTE) of the amorphous glass substrate is 3.5×10⁻⁶ [1/K] to 4.0×10⁻⁶ [1/K], and
a softening point of the amorphous glass substrate is 950° C. to 1050° C.

2. The laminate according to claim 1, wherein an arithmetic mean roughness (Ra) on a surface of the amorphous glass substrate is equal to or less than 3 nm.

3. The laminate according to claim 1, wherein the amorphous glass substrate has a local Si—O crystal structure.

4. The laminate according to claim 1, wherein the AlN layer is a thin film deposited and formed on the amorphous glass substrate.

5. The laminate according to claim 4, wherein the AlN layer is deposited and formed on the amorphous glass substrate at a deposition temperature of 400° C. to 600° C.

6. The laminate according to claim 5, wherein a film thickness of the AlN layer is 20 nm to 400 nm.

7. The laminate according to claim 6, wherein the AlN layer is in direct contact with the amorphous glass substrate.

8. The laminate according to claim 1, wherein a thickness of the amorphous glass substrate is 0.4 mm to 1.0 mm.

9. A method of manufacturing a laminate, the method comprising:
preparing an amorphous glass substrate having a glass transition temperature (Tg) of 720° C. to 810° C., a coefficient of thermal expansion (CTE) of 3.5×10⁻⁶ [1/K] to 4.0×10⁻⁶ [1/K], and a softening point of 950° C. to 1050° C.; and
forming an AlN layer on the amorphous glass substrate at a deposition temperature of 400° C. to 600° C.

10. The method of manufacturing a laminate according to claim 9, wherein, at the forming, the AlN layer is c-axis oriented on the amorphous glass substrate and the AlN layer is deposited and formed with a film thickness of 20 nm to 400 nm.

11. The method of manufacturing a laminate according to claim 10, wherein the AlN layer is deposited on the amorphous glass substrate by sputtering.
